(19) United States
(12) Patent Application Publication
(10) Pub. No.: US 2008/0186087 A1
(43) Pub. Date: Aug. 7, 2008

(54) Method and apparatus for reducing electromagnetic interference

(75) Inventor: Chien-Neng Chang, Gueishan (TW)

Correspondence Address: BIRCH STEWART KOLASCH & BIRCH, PO BOX 747, FALLS CHURCH, VA, 22040-0747, US

(73) Assignee: Qisda Corporation

(21) Appl. No.: 12/010,615

(22) Filed: Jan. 28, 2008

(30) Foreign Application Priority Data
Feb. 6, 2007 (TW) 096104208

(51) Int. Cl. H04B 1/10; G01R 23/02

(52) U.S. Cl. 327/551; 327/39

(57) ABSTRACT

An apparatus for reducing electromagnetic interference is provided. The apparatus includes a receiving module, a first comparing module, and a frequency spreading module. The receiving module receives a first signal with a first frequency and a second signal with a second frequency. The first comparing module is used for comparing the first frequency and the second frequency. The frequency spreading module is operated by a comparing result of the first comparing module. If the first frequency is higher than the second frequency, the frequency spreading module up-spreads the first frequency and down-spreads the second frequency.

### BACKGROUND OF THE INVENTION

1. Field of the Invention

This invention generally relates to signal processing methods and signal processing apparatuses. More specifically, the invention is related to methods and apparatuses for reducing electromagnetic interference.

2. Description of the Prior Art

In today's electronic systems, with the increasing operating speed of circuits, electromagnetic interference (EMI) caused by clock signals has become a problem that cannot be neglected. In addition, to increase the operating frequency and effective working time, circuits designers generally make the rising time of a clock signal be as short as possible. However, steeper rising edges inevitably introduce more high-frequency components and more serious EMI problem.

There have been many methods for diminishing EMI: shielding sensitive circuits, controlling the waveform of clock signals, controlling the slope of rising edges in clock signals, staggering the output timing of different signals, and spread spectrum. Among these solutions, spread spectrum is the simplest and most efficient one. It also offers the best immunity with respect to variations in manufacturing processes.

The concept of spread spectrum is to slightly modulate the frequency of a clock signal and to evenly spread its energy (i.e. spectrum) over a controllable small range. Thereby, energy peaks corresponding to harmonic frequencies of the clock signal are diminished. Because this approach reduces every energy peak of all harmonic components, EMI induced by the clock signal can be effectively reduced by spread spectrum techniques.

Existing spread spectrum techniques can be further divided into three categories: center-spread, up-spread, and down-spread. Assume a clock signal has a center frequency represented as F_{C}. If the clock signal is center-spread with a spread amount equal to 1%, the frequency of the clock signal will be spread over the range of F_{C}±0.005*F_{C}. In other words, the center frequency of the clock signal is still F_{C}. If the clock signal is up-spread with a spread amount equal to 1%, the frequency of the clock signal will be spread over the range between F_{C} and (F_{C}+0.01*F_{C}). On the contrary, if the clock signal is down-spread with a spread amount equal to 1%, the frequency of the clock signal will be spread over the range between F_{C} and (F_{C}−0.01*F_{C}).

Generally, there are many clock signals with various frequencies in an IC chip at the same time. However, prior arts only perform spread spectrum respectively on each of the clock signals; whether energies of those signals adjacent to each other in frequency domain will be stacked is not considered.

Please refer to FIGS. 1(A) and 1(B), which illustrate an example of adjacent energy stacking. In this example, the center frequencies of a first clock signal and a second clock signal are respectively represented as F₁ and F₂. As shown in FIG. 1(A), before spread spectrum, the second clock signal is adjacent to the first clock signal. As shown in FIG. 1(B), after spread spectrum, both the energy peaks corresponding to the two frequencies, F₁ and F₂, are decreased. However, because the two frequencies are close to each other, after spread spectrum, parts of their energies are overlapped and accordingly stacked. Unfortunately, the stacked energy increases EMI and transgresses the original purpose of spread spectrum.

Furthermore, whether energies of harmonic components will be stacked is not considered in prior arts either. For instance, assume the center frequencies of a first clock signal and a second clock signal are respectively 12 MHz and 20 MHz. The lowest common multiple frequency of the two frequencies is 60 MHz. This common multiple frequency is the fifth harmonic frequency of 12 MHz and the third harmonic frequency of 20 MHz. Generally, the harmonic component of a higher order has less energy. The fifth and third harmonic components are both low ordered components that have high energies. Therefore, although the first and second clock signals are not adjacent to each other in the frequency domain, the energies of their harmonic components are still stacked after spread spectrum and introduce serious EMI.

### SUMMARY OF THE INVENTION

To solve the aforementioned problems, the invention provides methods and apparatuses for reducing electromagnetic interference. In the methods and apparatuses according to the invention, spread spectrum policies are adaptively adjusted to prevent the problems of adjacent energy stacking and harmonic energy stacking.

One embodiment according to the invention is a signal processing method for reducing electromagnetic interference. In the method, a first signal with a first frequency and a second signal with a second frequency are first received. Then, the first frequency and the second frequency are compared. If the first frequency is higher than the second frequency, the first frequency of the first signal is up-spread to generate a third signal, and the second frequency of the second signal is down-spread to generate a fourth signal.

Another embodiment according to the invention is a signal processing apparatus for reducing electromagnetic interference. The apparatus includes a receiving module, a first comparing module, and a frequency spreading module. The receiving module is used for receiving a first signal with a first frequency and a second signal with a second frequency. The first comparing module is used for comparing the first frequency and the second frequency. The frequency spreading module is operated by a comparing result of the first comparing module. If the first frequency is higher than the second frequency, the frequency spreading module up-spreads the first frequency and down-spreads the second frequency.

The advantage and spirit of the invention may be understood by the following recitations together with the appended drawings.

### BRIEF DESCRIPTION OF THE APPENDED DRAWINGS

FIG. 1(A) and FIG. 1(B) illustrate an example of adjacent energy stacking

FIG. 2(A) illustrates the flowchart of the signal processing method in the first embodiment according to the invention.

FIG. 2(B) illustrates the flowchart of the signal processing method in the second embodiment according to the invention.

FIG. 2(C) illustrates the flowchart of the signal processing method in the third embodiment according to the invention.

FIG. 3(A) and FIG. 3(B) illustrate an exemplary spectrum relative to the signal processing method according to the invention.

FIG. 4(A) illustrates the block diagram of the signal processing apparatus in the fourth embodiment according to the invention.

FIG. 4(B) illustrates the block diagram of the signal processing apparatus in the fifth embodiment according to the invention.

FIG. 4(C) illustrates the block diagram of the signal processing apparatus in the sixth embodiment according to the invention.

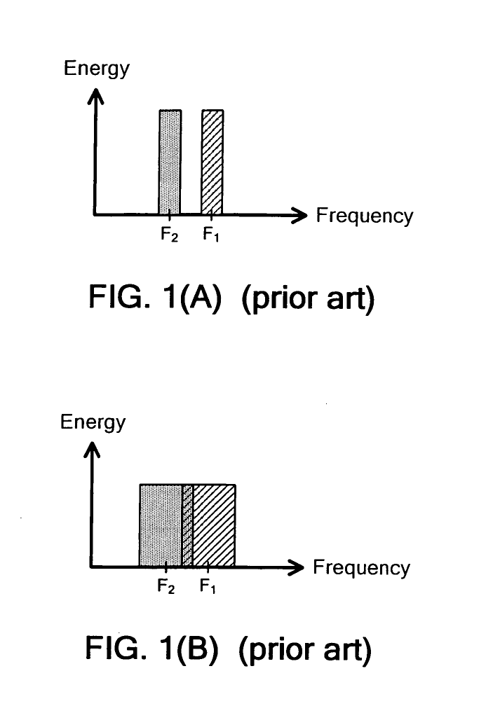

### DETAILED DESCRIPTION OF THE INVENTION

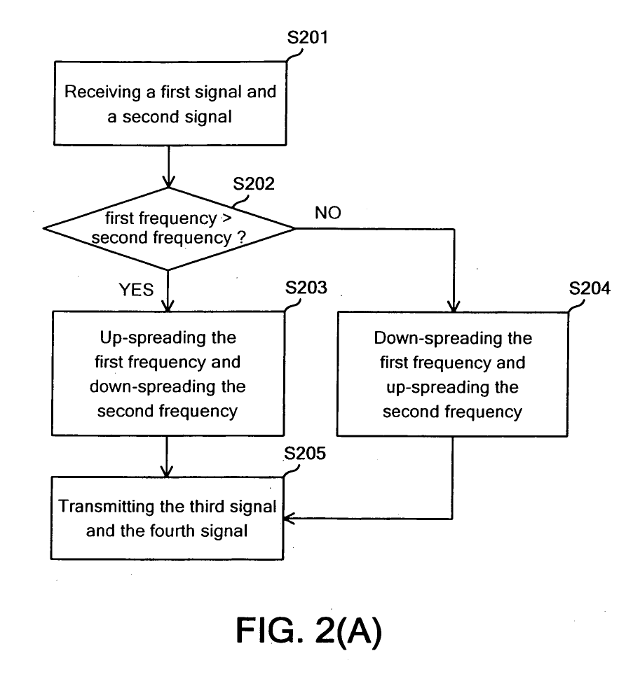

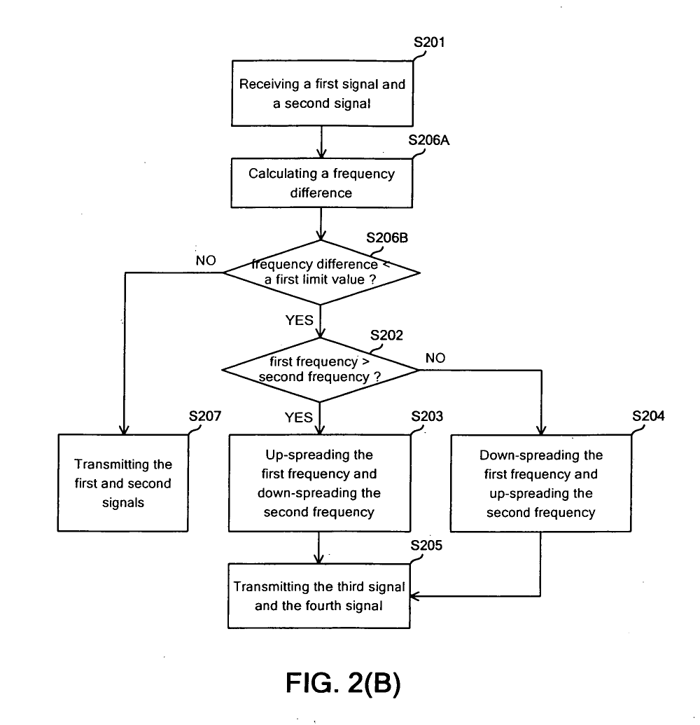

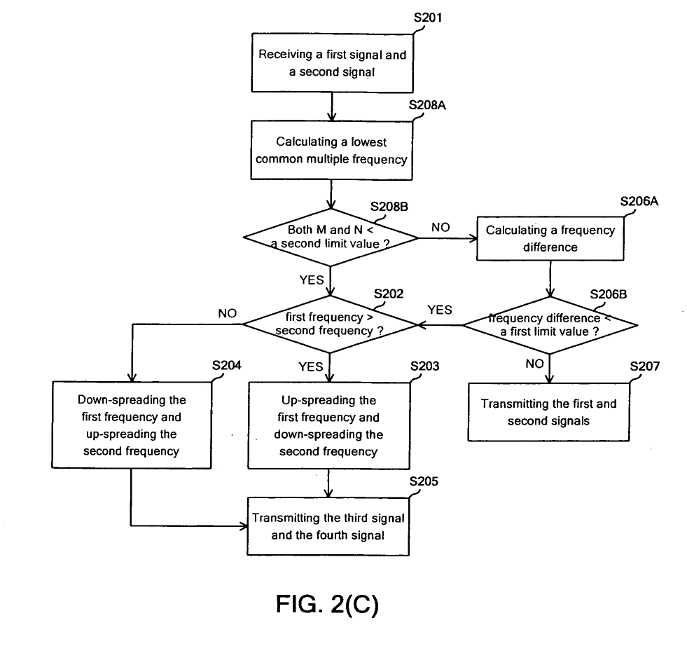

The first embodiment, according to the invention, is a signal processing method for reducing electromagnetic interference in an electronic device. Please refer to FIG. 2(A), which illustrates the flowchart of this method. In step S201, a first signal with a first frequency and a second signal with a second frequency are received. Then, in step S202, the first frequency and the second frequency are compared. If the first frequency is higher than the second frequency, step S203 is performed to up-spread the first frequency of the first signal to generate a third signal and down-spread the second frequency of the second signal to generate a fourth signal.

On the contrary, if the first frequency is lower than the second frequency, step S204 is performed. In step S204, the first frequency of the first signal is down-spread to generate the third signal, and the second frequency of the second signal is up-spread to generate the fourth signal. After step S203 or step S204, step S205 is performed to transmit the third and fourth signals to the electronic device.

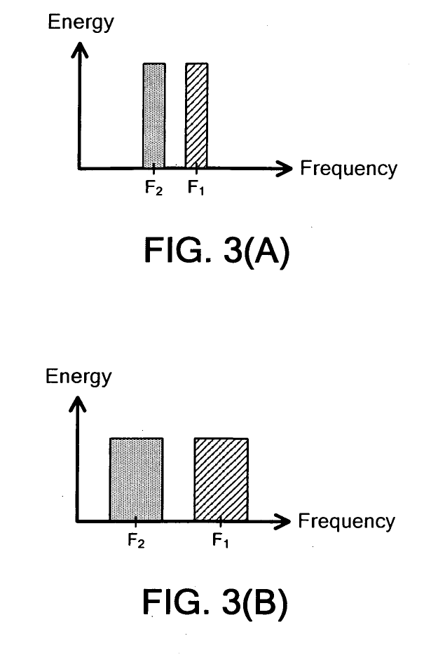

Please refer to FIG. 3(A) and FIG. 3(B), which illustrate an exemplary spectrum relative to the aforementioned method. The original spectrum of the first and second signals is shown in FIG. 3(A). In this example, the first frequency (F₁) is higher than the second frequency (F₂). Therefore, according to the above method, the first frequency is up-spread, and the second frequency is down-spread. In FIG. 3(B), the spectrum of the third and fourth signals is shown. It can be seen, because the spread “directions” for the first and second signals are opposite, the energies of the third and fourth signals will not be stacked. Thereby, the problem of adjacent energy stacking is prevented.

The second embodiment, according to the invention, is also a signal processing method for reducing electromagnetic interference in an electronic device. Please refer to FIG. 2(B), which illustrates the flowchart of this method. Compared with the first embodiment, this method further includes steps S206A, S206B, and S207.

As shown in FIG. 2(B), steps S206A and S206B are performed between S201 and S202. In step S206A, a frequency difference between the first frequency and the second frequency is calculated. In step S206B, it is judged if the frequency difference is smaller than a first limit value. In other words, step S206B is performed to judge whether the first and second signals are adjacent to each other. If the judging result of step S206B is NO, it implies that there should not be energy stacking problem for the first and second signals. Therefore, step S207 is then performed to directly output the first and second signals to the electronic device. On the contrary, if the judging result of step S206B is YES, steps S202˜S205 are subsequently performed.

For instance, if the first frequency is 42 MHz, and the second frequency is 43 MHz, the frequency difference will be 1 MHz. Assume that before the method according to the invention is applied, center-spread is performed respectively on the first and second signals, and the spread amount is 3%. After being center-spread, the frequency of the first signal will be spread over the range of 41.37˜42.63 MHz, and the frequency of the second signal will be spread over the range of 42.36˜43.65 MHz. Evidently, some of the spread energies of the two signals will be stacked, and a new energy peak is introduced.

In actual applications, if the first and the second frequencies are represented as F₁ and F₂, respectively, the first limit value can be equal to (0.5*F₁*S₁+0.5*F₂*S₂), wherein S₁ is a first spread amount for the first signal, and S₂ is a second spread amount for the second signal.

If the first limit value in the embodiment above is 2 MHz, according to the invention, the first signal should be down-spread, and the second signal should be up-spread. After being down-spread, the frequency of the first signal will be spread over the range of 40.74˜42 MHz. After being up-spread, the frequency of the second signal will be spread over the range of 43˜44.29 MHz. Through this method, the energy stacking problem is accordingly solved.

The third embodiment, according to the invention, is also a signal processing method for reducing electromagnetic interference in an electronic device. Please refer to FIG. 2(C), which illustrates the flowchart of this method. Compared with the second embodiment, this method further includes steps S208A and S208B. As shown in FIG. 2(C), steps S208A and S208B are performed between steps S201, S202, and S206A.

In step S208A, a lowest common multiple frequency based on the first frequency and the second frequency is calculated. The lowest common multiple frequency is the Mth harmonic frequency of the first frequency and the Nth harmonic frequency of the second frequency, wherein M and N are positive integers. In step S208B, it is judged whether M and N are both smaller than a second limit value.

As described above, the harmonic component of a higher order has less energy. Therefore, energy stacking of two high order harmonic components does not introduce large EMI. If the judging result of step S208B is NO, it implies that there should not be harmonic energy stacking problem for the first and second signals. Accordingly, if the judging result of step S208B is NO, step S206A is then performed to judge if the two signals are adjacent to each other. If the judging result of step S208B is YES, steps S202˜S205 are subsequently performed. After respectively up/down spreading the first and second signals, every harmonic component of the two signals will also be correspondingly up/down spread. Hence, respectively up/down spreading the first and second signals can solve the harmonic energy stacking problem for the two signals.

For instance, if the first frequency is 30 MHz, and the second frequency is 45 MHz, the lowest common multiple frequency will be 90 MHz. This common multiple frequency is the frequency of the third harmonic component for the first signal and also the frequency of the second harmonic component for the second signal. In other words, in this example, M equals 3, and N equals 2. According to the embodiment above, if the second limit value is 7, the first signal should be down-spread and the second signal should be up-spread.

In actual applications, the number of clock signals to be inputted into the electronic device may be more than two. Assume, besides the first and second signals, a fifth signal with a fifth frequency will also be inputted into the electronic device. According to the invention, if the aforementioned lowest common multiple frequency is the Pth harmonic frequency of the fifth frequency, and P is a positive integer smaller than the second limit value, then at least one rising edge of the fifth signal will be delayed. Staggering the rising edges of two signals can prevent energy stacking problem, too.

Assume that the first, second, and third frequencies are respectively 30 MHz, 45 MHz, and 33 MHz, and the second limit value is 7. Because the second through the seventh multiple frequencies of 33 MHz are all not multiple frequencies of 30 MHz or 45 MHz, there will not be harmonic energy stacking problem between the fifth and the first/second signals. Therefore, in the method according to the invention, the first and second signals are respectively up and down spread, and the fifth signal can be directly center-spread.

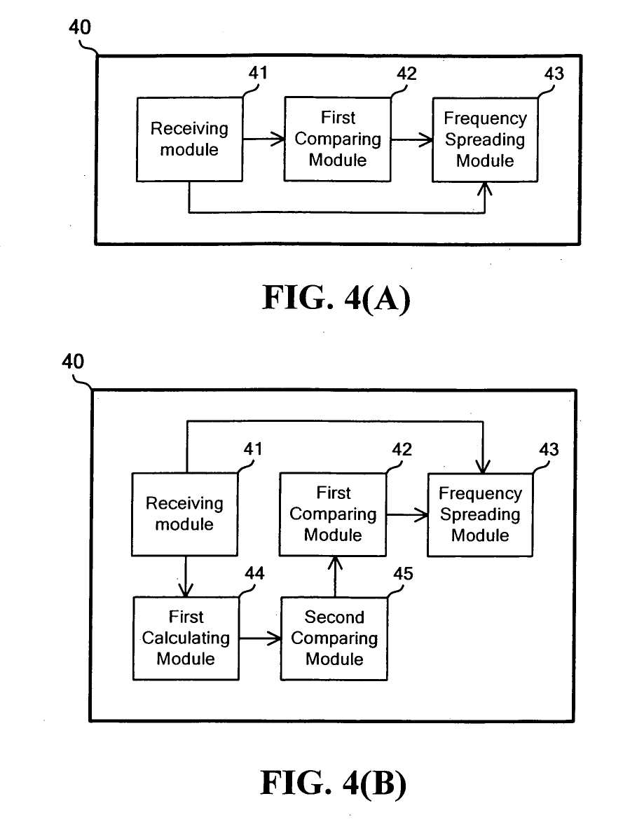

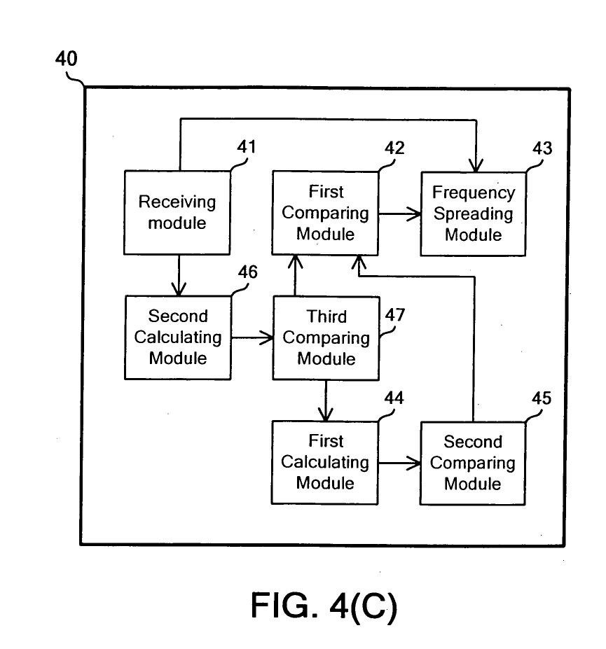

The fourth embodiment according to the invention is a signal processing apparatus for reducing electromagnetic interference. Please refer to FIG. 4(A), which illustrates the block diagram of the signal processing apparatus 40. The signal processing apparatus 40 includes a receiving module 41, a first comparing module 42, and a frequency spreading module 43.

The receiving module 41 is used for receiving a first signal with a first frequency and a second signal with a second frequency. The first comparing module 42 is used for comparing the first frequency and the second frequency. The frequency spreading module 43 is operated by a comparing result of the first comparing module 42. If the first frequency is higher than the second frequency, the frequency spreading module 43 up-spreads the first frequency of the first signal to generate a third signal and down-spreads the second frequency of the second signal to generate a fourth signal.

On the contrary, if the first frequency is lower than the second frequency, the frequency spreading module 43 down-spreads the first frequency of the first signal to generate the third signal and up-spreads the second frequency of the second signal to generate the fourth signal.

The fifth embodiment according to the invention is also a signal processing apparatus for reducing electromagnetic interference. As shown in FIG. 4(B), in this embodiment, the signal processing apparatus 40 further includes a first calculating module 44 and a second comparing module 45. The first calculating module 44 is used for calculating a frequency difference between the first frequency and the second frequency. The second comparing module 45 is used for comparing the frequency difference with a first limit value. If the frequency difference is smaller than the first limit value, the second comparing module 45 will operate the first comparing module 42 to compare the first frequency and the second frequency.

The sixth embodiment according to the invention is also a signal processing apparatus for reducing electromagnetic interference. Compared with the aforementioned fifth embodiment, this embodiment further includes a second calculating module 46 and a third comparing module 47 as shown in FIG. 4(C). The second calculating module 46 is used for calculating a lowest common multiple frequency based on the first frequency and the second frequency. The lowest common multiple frequency is the Mth harmonic frequency of the first frequency and the Nth harmonic frequency of the second frequency, wherein M and N are positive integers. The third comparing module 47 is used for comparing M and N with a second limit value. If M and N are both smaller than the second limit value, the third comparing module 47 will operate the first comparing module 42 to compare the first frequency and the second frequency.

As described above, because the methods adjust frequency spreading policies adaptively, the problems of adjacent energy stacking and harmonic energy stacking can be prevented.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method for reducing electromagnetic interference in an electronic device, comprising:
(a) receiving a first signal with a first frequency and a second signal with a second frequency;
(b) comparing the first frequency and the second frequency;
(c) if the first frequency is higher than the second frequency, up-spreading the first frequency of the first signal to generate a third signal and down-spreading the second frequency of the second signal to generate a fourth signal; and
(d) transmitting the third signal and the fourth signal to the electronic device.

2. The method of claim 1, further comprising:
(e) if the first frequency is lower than the second frequency, down-spreading the first frequency of the first signal to generate the third signal and up-spreading the second frequency of the second signal to generate the fourth signal.

3. The method of claim 1, further comprising:
(f1) before step (b), calculating a frequency difference between the first frequency and the second frequency; and
(f2) if the frequency difference is smaller than a first limit value, performing step (b).

4. The method of claim 3, wherein the first and the second frequencies are represented as F₁ and F₂, respectively, the first limit value is equal to (0.5*F₁*S₁+0.5*F₂*S₂), wherein S₁ is a first spread amount for the first signal, and S₂ is a second spread amount for the second signal.

5. The method of claim 1, further comprising:
(g1) before step (b), calculating a lowest common multiple frequency based on the first frequency and the second frequency, the lowest common multiple frequency being the Mth harmonic frequency of the first frequency and the Nth harmonic frequency of the second frequency, wherein M and N are positive integers; and
(g2) performing step (b) if M and N are both smaller than a second limit value.

6. The method of claim 5, further comprising:
(g3) if M and N are both larger than or equal to the second limit value, calculating a frequency difference between the first frequency and the second frequency; and
(g4) performing step (b) if the frequency difference is smaller than a first limit value.

7. The method of claim 5, wherein a fifth signal has a fifth frequency, the lowest common multiple frequency is the Pth harmonic frequency of the fifth frequency, P is a positive integer smaller than the second limit value, and at least one rising edge of the fifth signal is delayed in step (g2).

8. An apparatus for reducing electromagnetic interference, comprising:
a receiving module for receiving a first signal with a first frequency and a second signal with a second frequency;
a first comparing module for comparing the first frequency and the second frequency; and
a frequency spreading module operated by a comparing result of the first comparing module, if the first frequency is higher than the second frequency, the frequency spreading module up-spreading the first frequency of the first signal to generate a third signal and down-spreading the second frequency of the second signal to generate a fourth signal.

9. The apparatus of claim 8, wherein if the first frequency is lower than the second frequency, the frequency spreading module down-spreads the first frequency of the first signal to generate the third signal and up-spreads the second frequency of the second signal to generate the fourth signal.

10. The apparatus of claim 8, further comprising:
a first calculating module for calculating a frequency difference between the first frequency and the second frequency; and
a second comparing module for comparing the frequency difference with a first limit value, if the frequency difference is smaller than the first limit value, the second comparing module operating the first comparing module to compare the first frequency and the second frequency.

11. The apparatus of claim 10, wherein the first and the second frequencies are represented as F₁ and F₂, respectively, the first limit value is equal to (0.5*F₁*S₁+0.5*F₂*S₂), wherein S₁ is a first spread amount for the first signal, and S₂ is a second spread amount for the second signal.

12. The apparatus of claim 8, further comprising:
a second calculating module for calculating a lowest common multiple frequency based on the first frequency and the second frequency, the lowest common multiple frequency being the Mth harmonic frequency of the first frequency and the Nth harmonic frequency of the second frequency, wherein M and N are positive integers; and
a third comparing module for comparing M and N with a second limit value, if M and N are both smaller than the second limit value, the third comparing module operating the first comparing module to compare the first frequency and the second frequency.

13. The apparatus of claim 12, further comprising:
a first calculating module, if M and N are both larger than or equal to the second limit value, the first calculating module calculating a frequency difference between the first frequency and the second frequency; and
a second comparing module for comparing the frequency difference with a first limit value, if the frequency difference is smaller than the first limit value, the second comparing module operating the first comparing module to compare the first frequency and the second frequency.

14. The apparatus of claim 12, wherein a fifth signal has a fifth frequency, the lowest common multiple frequency is the Pth harmonic frequency of the fifth frequency; P is a positive integer smaller than the second limit value, and the frequency spreading module delays at least one rising edge of the fifth signal.
